(19) United States
(12) Patent Application Publication
(10) Pub. No.: US 2024/0404040 A1
(43) Pub. Date: Dec. 5, 2024

(54) TEST SYSTEM AND TEST METHOD TO WAFERS

(71) Applicant: NANYA TECHNOLOGY CORPORATION, New Taipei City (TW)

(72) Inventor: Chia-Lin TSAI, Chiayi City (TW)

(21) Appl. No.: 18/326,018

(22) Filed: May 31, 2023

(51) Int. Cl. G06T 7/00

(52) U.S. Cl. CPC G06T 7/001; G06T 2207/20081; G06T 2207/20084; G06T 2207/30148; G06T 2207/30204

(57) ABSTRACT

A test system is provided, including an assessment subsystem, a neural network subsystem and a process control processor. The assessment subsystem receives a test image of a tested wafer from a probe apparatus. The process control processor controls, in response to the probe apparatus obtaining the test image, the assessment subsystem to perform an assessment operation to transmit the test image to the neural network subsystem in an automation mode. The neural network subsystem identifies an image specification of probe marks in the test image and generates an analyzed data of the test image to the assessment subsystem. The assessment subsystem further generates a first probe mark inspection result based on the analyzed data to the process control processor for generating a test result.

### BACKGROUND

### Description of Related Art

In integrated circuit manufacturing technology, testing is a final step for detecting defects generated during the integrated circuit fabrication process and determining the root causes of these defects. Prior to the packaging process, circuit probe testing is performed among the wafers to verify that each die meets product specifications.

With probe mark inspections being performed by operators, human errors may be introduced in the process, which affects test quality and highly time consuming. For example, test cycle time and yield is impacted. Detection of probe mark based on the customer complaints also affects the overall service quality of the manufacturer and the need for operators and engineers increase the cost of production. As a result, the time to market, scrap ratio, and product quality are impacted. Therefore, a huge demand exists for a method and system that automatically analyze probe marks and take corrective action, such that customer service quality may be improved.

### SUMMARY

One aspect of the present disclosure is to provide a test system including an assessment subsystem, a neural network subsystem and a process control processor. The assessment subsystem receives a test image of a tested wafer from a probe apparatus. The process control processor controls, in response to the probe apparatus obtaining the test image, the assessment subsystem to perform an assessment operation to transmit the test image to the neural network subsystem in an automation mode. The neural network subsystem identifies an image specification of probe marks in the test image and generates an analyzed data of the test image to the assessment subsystem. The assessment subsystem further generates a first probe mark inspection result based on the analyzed data to the process control processor for generating a test result.

In some embodiments, the assessment subsystem further generates, by comparing the test image and an analyzed image in the analyzed data, a training data to the neural network subsystem. The training data includes the test image and a corresponding identification data.

In some embodiments, the neural network subsystem is be trained by the training data to update weight values in a neural network model operating in a neural network processor in the neural network subsystem.

In some embodiments, the image specification includes coordination of the probe marks, an amount of the probe marks, inspection of a substrate of at least one pad in the tested wafer, or the combinations thereof.

In some embodiments, the assessment subsystem is configured to compare the analyzed data with multiple quality thresholds, and to generate the first probe mark inspection result indicating a first failure result when at least one value in the analyzed data fails to meet a corresponding threshold in the quality thresholds.

In some embodiments, the process control processor generates the test result indicating a second failure result in response to the first probe mark inspection result indicating the first failure result.

In some embodiments, the analyzed data includes distances between the probe marks and edges of pads in the tested wafer.

In some embodiments, the test system further includes a database subsystem having a data server configured to store the test image, the analyzed data and the first probe mark inspection result in a list data. The assessment subsystem accesses the list data and to generate a second probe mark inspection result based on the list data and a second quality threshold.

In some embodiments, the neural network subsystem accesses the list data and to be trained by a training data to update a neural network model operating in the neural network subsystem.

In some embodiments, the assessment subsystem performs the assessment operation for multiple images of multiple lots according to a work queue provided by the process control processor.

Another aspect of the present disclosure is to provide a test method including the operations as below: obtaining, by a probe apparatus, a plurality of test images of a lot of wafers; marking, by a neural network subsystem, the plurality of test images based on a corresponding image specification of probe marks in each the plurality of test images to generate a plurality of marked images in a plurality of analyzed data; comparing, by an assessment subsystem, the plurality of test images and the plurality of marked images to generate a comparison result for each of the wafers in the lot; in response to the comparison, generating a first probe mark inspection result; and updating a record, corresponding to the lot of wafers, in a process control processor according to the first probe mark inspection result.

In some embodiments, the corresponding image specification of the probe marks includes coordination of the probe marks, an amount of the probe marks, inspection of a substrate of pads in the lot of the wafers, distances between the probe marks and edges of the pads in the lot of the wafer, or the combinations thereof.

In some embodiments, the test method further includes determining whether the plurality of analyzed data meet a plurality of quality thresholds to generate a second mark inspection result.

In some embodiments, when the comparison result indicates an accurate result, the generating the first probe mark inspection result includes: in response to the comparison result, generating the first probe mark inspection result indicating a pass result.

In some embodiments, when at least one mark on the plurality of marked images mismatches a correcting mark, the corresponding comparison result indicates an inaccurate result.

In some embodiments, the test method further includes generating a plurality of training data according to the correcting mark and the plurality of test images; and training a neural network model in the neural network subsystem according to the plurality of training data.

In some embodiments, the corresponding image specification of the probe marks includes an amount of the probe marks on a pad in one, corresponding to a wafer in the lot of wafers, of the plurality of test images. The test method further includes when the amount of the probe marks on the pad in one of the plurality of analyzed data is greater than a threshold, generating a second probe mark inspection result indicating a failure result; and updating the record according to the second probe mark inspection result.

In some embodiments, the corresponding image specification of the probe marks includes inspection of a substrate of pads in the lot of the wafers and an amount of the probe marks on a first pad of the pads in one, corresponding to a wafer in the lot of wafers, of the plurality of test image. The test method further includes when the inspection of the substrate indicates that no material of the substrate appears on at least one pad of the pads, determining whether the amount of the probe marks on the first pad is greater than a first threshold; and when the amount of the probe marks on the first pad is greater than the first threshold, generating a second probe mark inspection result indicating a failure result.

In some embodiments, the test method further includes when the amount of the probe marks on the first pad is less than the first threshold, generating the second probe mark inspection result indicating a pass result; and dispatching the lot of the wafer from the probe apparatus to a process stage.

In some embodiments, the test method further includes when the amount of the probe marks on the first pad is less than the first threshold, determining whether distances between the probe marks on the first pad and edges of the first pad is within a second threshold; and when the distance is out of a range of the second threshold, generating the second probe mark inspection result indicating the failure result.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a test system, in accordance with some embodiments of the present disclosure.

FIG. 2 is a schematic diagram of a test image corresponding to part of a tested wafer, in accordance with some embodiments of the present disclosure.

FIG. 3 is a schematic diagram of a test method, in accordance with some embodiments of the present disclosure.

FIG. 4 is a schematic diagram of a control interface in the test system in FIG. 1, in accordance with another embodiment of the present disclosure.

FIG. 5 is a block diagram of a processing device of a test system in accordance with some embodiments of the present disclosure.

### DETAILED DESCRIPTION

The spirit of the present disclosure will be discussed in the following drawings and detailed description, and those of ordinary skill in the art will be able to change and modify the teachings of the present disclosure without departing from the spirit and scope of the present disclosure.

It should be understood that, in this document and the following claims, when an element is referred to as being “connected” or “coupled” to another element, it can be directly connected or coupled to another element, or there may be an intervening component. In contrast, when an element is referred to as being “directly connected” or “directly coupled” to another element, there is no intervening element. In addition, “electrically connected” or “connected” may also be used to indicate that two or more elements cooperate or interact with each other.

It should be understood that, in this document and the following claims, the terms “first” and “second” are to describe the various elements. However, these elements should not be limited by these terms. These terms are used to distinguish one element from another. For example, a first element may be termed a second element. Similarly, a second element may be termed a first element without departing from the spirit and scope of the embodiments.

It should be understood that, in this document and the following claims, the terms “include,” “comprise,” “having” and “has/have” are used in an open-ended fashion, and thus should be interpreted to mean “include, but not limited to.”

It should be understood that, in this document and the following claims, the term “and/or” includes any and all combinations of one or more of the associated listed items.

In some embodiments, the test system and the test method of the present disclosure receive the test images of wafers and perform probe marks assessment operation automatically to classify devices on the wafers according to probe marks on pads in the devices through neural network model recognition. Furthermore, the process control processor, referred to as an accounting system in some embodiments, transmits the test result to alarm irregularity in products or process before shipping. With configurations of the present disclosure, integration of testing equipment and artificial intelligent identification facilitates automation test control system in manufacturing process to significantly reduce manual effort, errors made thereby, and further to enhance overall productivity.

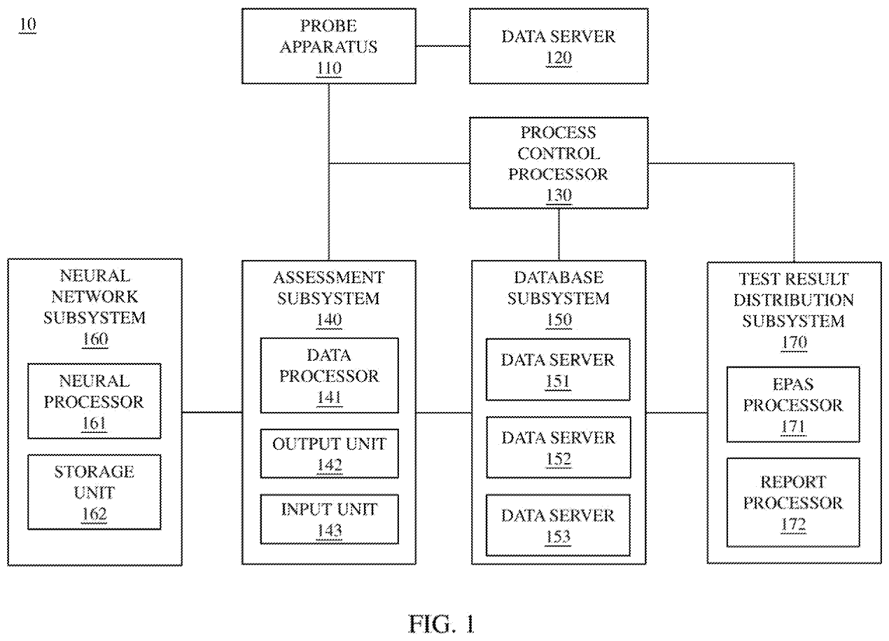

Reference is now made to FIG. 1. FIG. 1 is a schematic diagram of a test system 10, in accordance with some embodiments of the present disclosure. In some embodiments, the test system 10 is configured as one of test stages for tested wafers in lots before shipping in order to evaluate the tested wafers. The test system 10 is a test stage utilizing optical testing to specify surface defect on the wafers. In some embodiments, the test system 10 is an automated system to generate test data of tested wafers for classifying the tested wafers to be shipped.

For illustration, the test system 10 includes a probe apparatus 110, a data server 120, a process control processor 130 and subsystems including an assessment subsystem 140, a database subsystem 150, a neural network subsystem 160 and test result distribution subsystem 170. The probe apparatus 110 connects the data server 120, the process control processor 130 and the assessment subsystem 140 for transmitting test data of tested wafers. The process control processor 130 further connects to control the assessment subsystem 140, the database subsystem 150 and the test result distribution subsystem 170 to generate test results corresponding to tested wafers for shipping. The neural network subsystem 160 is trained based on the test images provided by the probe apparatus 110 and provides inspection results of the real-time test images to the assessment subsystem 140 for generating test results automatically.

In some embodiments, the probe apparatus 110 includes a camera device configured to capture test images of a lot of tested wafers transmitted to the test stage where the test system 10 is. The test images include surface image of device under tests (DUT) on the tested wafers. For example, in some embodiments, pads on the DUT of the tested wafers contact probes in previous test stage and the test images specifically include probe marks left by the pins on pads on the DUT. In some embodiments, the camera may be a complementary metal-oxide semiconductor (CMOS) camera, a charge-coupled device (CCD) camera, a video camera, or another suitable type of camera.

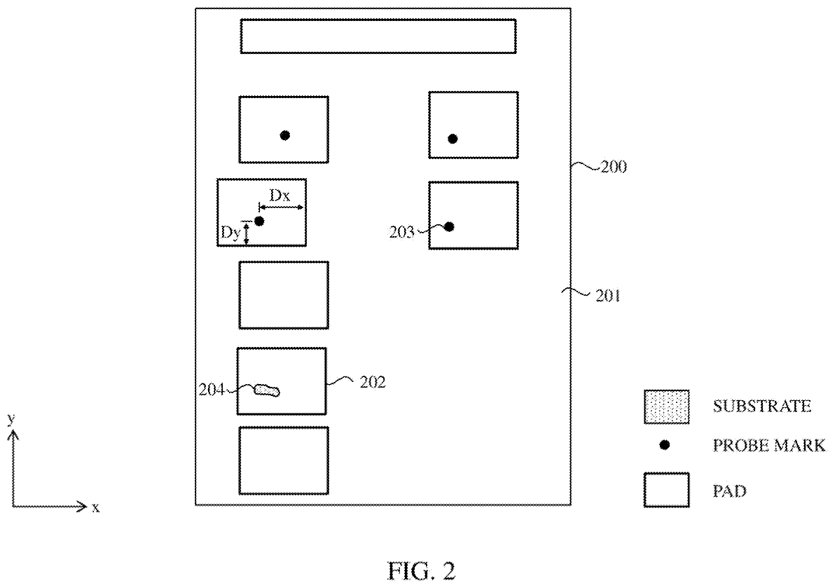

Reference is now made to FIG. 2. FIG. 2 is a schematic diagram of a test image 200 corresponding to part of a tested wafer 201, in accordance with some embodiments of the present disclosure. For illustration, the test image 200 corresponding to part of the tested wafer 201 includes several pads 202. As shown in the embodiments of FIG. 2, probe marks 203 are on portions of the pad 202 in which one of the probe marks 203 is apart from edges of the pad 202 by a distance Dx in a x direction and a distance Dy in a y direction. A crack portion 204 in the 202 exposes a substrate region of the tested wafer 201. In some embodiments, the crack portion 204 is produced by a heavy contacting between the probe and the pad 20, which shaves metal cover material off the pad and reveals the substrate region that is beneath the pad.

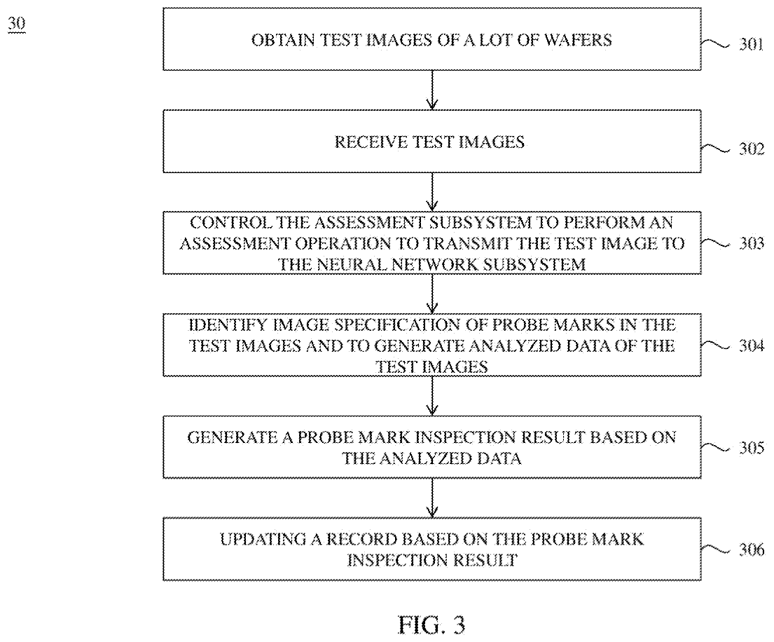

Reference is now made to FIG. 3. FIG. 3 is a schematic diagram of a test method 300, in accordance with some embodiments of the present disclosure. It is understood that additional operations can be provided before, during, and after the processes shown by FIG. 3, and some of the operations described below can be replaced or eliminated, for additional embodiments of the test method 300. The test method 300 includes operations 301-306 that are described below with reference to FIGS. 1-4. In some embodiments, the test method 300 is performed by the test system 10 as shown in FIGS. 1-2 and 4.

In operation 301, the probe apparatus 110 obtains test images, for example, the test image 200 in FIG. 2, of a lot of tested wafers, in which the lot is transmitted to the probe apparatus 110 from the previous test stage, for example, being a test stage for electrical specification of devices on the tested wafers.

In operation 302, the assessment subsystem 140 receives the test images 200 from the probe apparatus 110. In some embodiments, the probe apparatus 110 also transmits the test images 200 and corresponding information (e.g., the lot number, the amount of wafers in the lot, the test time, etc.) to the data server 120.

In operation 303, the process control processor 130 controls, in response to the probe apparatus 110 obtaining the test images 200, the assessment subsystem 140 to perform an assessment operation to transmit the test images 200 to the neural network subsystem 160 in an automation mode.

In some embodiments, the test method 300 further includes operations of the assessment subsystem 140 transmitting the test images 200 and corresponding information to a data server 151 of the database subsystem 150 in response to a command sent by the process control processor 130.

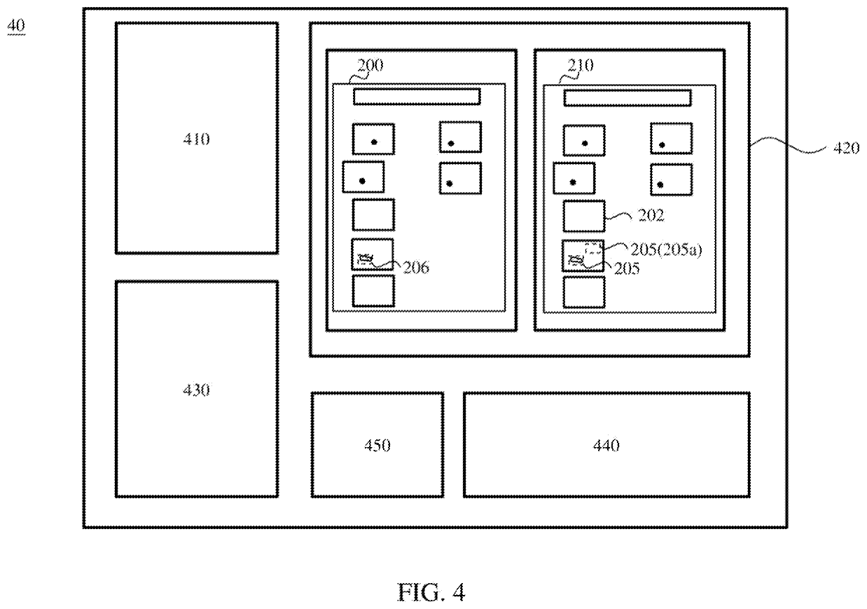

In some other embodiments, when there are multiple lots of tested wafers under testing, the process control processor 130 is further configured to provide a work queue for the assessment subsystem 140, and accordingly the assessment subsystem 140 perform the assessment operation lot by lot based on the work queue. For example, with reference to FIG. 4, FIG. 4 is a schematic diagram of a control interface 40 in the test system 10 in FIG. 1, in accordance with another embodiment of the present disclosure. In some embodiments, an output unit 142 of the assessment subsystem 140 provides the control interface 40 according to operations/codes/data received from a data processor 141 in the assessment subsystem 140. The work queue is shown in the block 410 of the control interface 40. In addition, the information about the corresponding tested wafer is shown in a block 430 and values (e.g., coordination of the probe marks 203, the amount of the probe marks 203, coordination and size of the marks 205, and/or other values related to the testing) in the analyzed data are shown in a block 440.

When the neural network subsystem 160 receives the test images 200, the neural network subsystem 160 in response identifies image specification of the probe marks 203 in the test images 200 and further generates analyzed data, including information corresponding to the image specification of the probe marks, of the test images 200 to the assessment subsystem 140 in operation 304. In some embodiments, image specification of the probe marks in the test images 200 are test data for inspection the quality of the tested wafers, which includes an amount of probe marks, coordination of probe marks with respect to a reference point on the tested wafers, inspection of substrate of pads, locations of probe marks with respect to edges of the pads, and/or other suitable specifications of the image, as discussion with respect to FIG. 2.

In some embodiments, the test method 300 further includes operations of marking, by the neural network subsystem 160, the test images 200 based on a corresponding image specification of probe marks 203 in each of the test images to generate marked images in the analyzed data. For example, with reference to FIG. 4, a marked image 210 (also referred to as analyzed image) in the analyzed data is shown in the control interface 40, having marks 205. Specifically, one of the mark 205 circles the crack portion 204 of the substrate of the pad 202. In some embodiments, coordination, size, and/or relevant parameters of the crack portion 204 are included in the analyzed data.

After the neural network subsystem 160 analyzes the test images 200, in operation 305, the assessment subsystem 140 generates a probe mark inspection result based on the analyzed data to the process control processor 130. In some embodiments, the assessment subsystem 140 compares the analyzed data with quality thresholds to generate the probe mark inspection result. For instance, the assessment subsystem 140 determines whether all values in the analyzed data meet the corresponding quality thresholds to generate the probe mark inspection result.

Specifically, in some embodiments, when the inspection of the substrate in the analyzed data meets a quality threshold indicating that no material of the substrate appears on the pad 202, the assessment subsystem 140 generates the probe mark inspection indicating a pass result to the process control processor 130.

In some embodiments, after examining the inspection of the substrate, the method further includes determining whether the amount of probe marks 203 on the pad in the corresponding analyzed data meets the threshold. For example, when the amount of probe marks 203 is less than the threshold being 5, the assessment subsystem 140 generates the probe mark inspection result indicating a pass result. In various embodiments, when the amount of probe marks 203 is greater than the threshold being 5, the assessment subsystem 140 generates the probe mark inspection result indicating a failure result.

Furthermore, in some embodiments, after examining the amount of the probe marks 203, the method further includes determining whether distances between the probe marks 203 and edges of the pad 202 in the corresponding analyzed data within a threshold. For example, when the distance Dx or Dy is within a certain range indicating that the probe marks 203 do not overlap the edges of the pad 202, the assessment subsystem 140 generates the probe mark inspection result indicating a pass result. In various embodiments, when the distance Dx or Dy is out of the range, indicating that the probe marks 203 overlap the edges of the pad 202, the assessment subsystem 140 generates the probe mark inspection result indicating a failure result.

In various embodiments, for certain quality criteria, the assessment subsystem 140 determines whether one value (e.g., one of factors in the image specification) in the analyzed data meets one quality threshold to generate the probe mark inspection result. For example, when the amount of the probe marks 203, the inspection of the substrate, or the distances between the probe marks and the edges of the pad 202 meets a corresponding threshold as discussed above, the assessment subsystem 140 generates the probe mark inspection indicating a pass result to the process control processor 130. In contrast, as the one value in the analyzed data fails to meet the corresponding quality threshold, the assessment subsystem 140 generates the probe mark inspection indicating a failure result to the process control processor 130.

In operation 306, a record in the process control processor 130 is updated according to the probe mark inspection. For example, when the probe mark inspection indicates a pass result, a macro test value as the test result in the record corresponding to the lot under testing in the test system 10 is updated from a first value (e.g., null) to a second value (e.g., pass) different from the first value. In contrast, when the probe mark inspection indicates a failure result, a macro test value in the record corresponding to the lot under testing in the test system 10 is updated from the first value (e.g., null) to a third value (e.g., fail) different from the first value.

In some embodiments, the method further includes operations of dispatching, through the test system 10 controlled by the process control processor 130, the lot of the tested wafers from the probe apparatus 110 to a process stage (not shown, for example, a marking stage before outgoing quality control (OQC) process) after the test system 10. Specifically, the process control processor 130 transmits a command to a electronic product/process abnormal system (EPAS) processor 171 of the test result distribution subsystem 170, and the EPAS processor 171 communicates with the probe apparatus 110 to dispatch the lot to the next process stage.

In some embodiments, the test images are saved in a storage unit 162 in the neural network subsystem 160 and further utilized to optimize a neural network model operating in a neural processor 161 of the neural network subsystem 160.

Specifically, in some embodiments, after the neural network subsystem 160 analyzing the test images, the test method 300 further includes operations of the assessment subsystem 140 comparing the test images 200 and the marked images 210 to generate corresponding comparison result for each of wafer in the lot to a data server 152 in the database subsystem 150. As shown in FIG. 4, the test image 200 and the marked image 210 are displayed in a block 420. In some embodiments, the assessment subsystem 140 further compares the image specification between the test image 200 and the analyzed image 210 based on an input signal and the analyzed data. For example, the amount of the probe marks 203 in the analyzed data provided by the neural network subsystem 160 is 3, which matches the amount of the probe marks 203 on the pad 202 in the test image 200 according to the input signal. Accordingly, the assessment subsystem 140 generates the comparison result indicating an accurate result and generates, based on the comparison result, the probe mark inspection result indicating the pass result to the process control processor 130.

In some embodiments, the input signal includes process data (e.g., the amount of probe marks made in the process, the locations of the probe marks . . . etc.) from previous process stage. For example, three probe marks are made by three electrical tests in the previous process stage. In various embodiments, the input signal is generated by an input unit 143 of the assessment subsystem 140 which is controlled by operators. For example, the operators can control the assessment subsystem 140 to perform image processing to mark, zoom in, zoom out, scale the items, rotate, adjust brightness and contrast, or conduct other suitable operation to the either the test image 200 or the analyzed image 210 based on the image processing tools shown in a block 450 of the control interface 40.

In contrast, when the image specification of the test image 200 does not match that of the analyzed image 210, the test method 300 further includes operations of the assessment subsystem 140 generating the comparison result indicating an inaccurate result and further correspondingly generating a training data, including the test image and corresponding identification data, to the neural network subsystem 160. For example, as shown in FIG. 4, in the analyzed image 210 are two marks 205 while only one area in the pad 202 exposes the substrate. Accordingly, the operator controls the input unit 143 to generate a correcting mark 206. The assessment subsystem 140 compares the test image 200 and the analyzed image 210 to determine that the mark 205a mismatches the correcting mark 206 and further generates the corresponding comparison result indicates an inaccurate result.

In some embodiments, the correcting mark is referred to as identification data and saved into a list data in a data server 152 of the database subsystem 150 along with the test image 200, the analyzed data and the probe mark inspection result corresponding to the lot of the tested wafers.

In some embodiments, the test method 300 further includes operations of the neural network subsystem 160 accessing the list data to train and to update a neural network model operating therein according to the training data in the list data. Specifically, parameters like weight values in the neural network model associated with the wrong mark 205a is adjusted (e.g., decreased), so that the neural network model is trained.

In some embodiments, when the quality criteria for shipping is adjusted based on product specification, the test method 300 further includes operations of the assessment subsystem 140 accessing the list data in the data server 152 and generating another probe mark inspection result based on the list data and the adjusted threshold. For example, the threshold of the amount of the probe marks 203 is adjusted from 5 to 10. The assessment subsystem 140 determines that the amount of the probe marks, equal to 6 and corresponding to a failure result of probe mark inspection result, is less than the adjusted threshold, and accordingly, the assessment subsystem 140 generates a probe mark inspection result indicating the pass result to update the record corresponding to the lot in the process control processor 130.

In some embodiments, as shown in FIG. 1, the test method 300 further includes operations of saving the test images 200, the analyzed data, corresponding information from the assessment subsystem 140 and the data server 151 into a backup data server 153 and generating a process/product report by a report processor 172 in the test result distribution subsystem 170 based on data stored in the backup data server 153.

The configurations of FIGS. 1-4 are given for illustrative purposes. Various implements are within the contemplated scope of the present disclosure. For example, in some embodiments, the amount of the probe marks 203 is a sum of probe marks on all pads 202 in the test image 200.

It should be noted that the test system 10 depicted in FIG. 1 may also include a processing device for realizing one or more of the tools, subsystems, methods, or operations described with respect to FIG. 1 to FIG. 4.

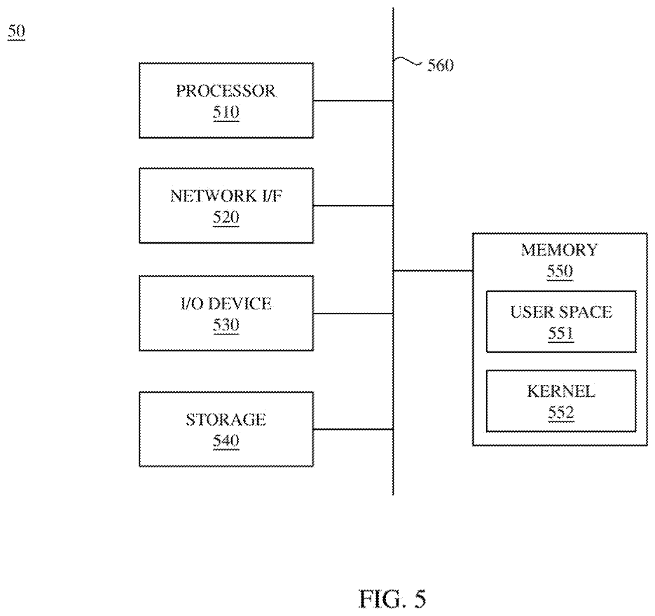

FIG. 5 is a block diagram of a processing device 50 of the test system 10 in accordance with some embodiments of the present disclosure. Alternatively stated, the probe apparatus 110, the data server 120, the process control processor 130, the assessment subsystem 140, the database subsystem 150, the neural network subsystem 160 and the test result distribution subsystem 170 are implemented by devices configured with respect to, for example, the processing device 50 shown in FIG. 5.

The processing device 50 may include a processor 510, a network interface (I/F) 520, an input/output (I/O) device 530, a storage device 540, and a memory 550 that are communicatively coupled via a bus 560 or other interconnection communication mechanism. The memory 550 includes, in some embodiments, a random access memory (RAM), other dynamic storage device, read-only memory (ROM), or other static storage device, coupled to the bus 560 for storing data or instructions to be executed by the processor 510, e.g., user space 551, kernel 552, portions of the kernel or the user space, and components thereof. The memory 550 is also used, in some embodiments, for storing temporary variables or other intermediate information during execution of instructions to be executed by the processor 510.

In some embodiments, a storage device 540, such as a magnetic disk or optical disk, is coupled to the bus 560 for storing data or instructions, e.g., kernel 552, user space 551, etc. The I/O device 530 includes an input device, an output device, or a combined input/output device for enabling user interaction with the test system 10. An input device comprises, for example, a keyboard, keypad, mouse, trackball, trackpad, or cursor direction keys for communicating information and commands to the processor 510. An output device includes, for example, a display, a printer, a voice synthesizer, etc. for communicating information to a user. In some embodiments, one or more operations or functionality of the tools or systems described with respect to FIGS. 1 to 4 are realized by the processor 510, which is programmed for performing such operations and functionality. One or more of the memory 550, the network I/F 520, the storage device 540, the I/O device 530, and the bus 560 are operable to receive instructions, data, design rules, netlists, layouts, models and other parameters for processing by the processor 510.

In some embodiments, one or more of the operations, functionality of the tools, and systems described with respect to FIG. 1 to FIG. 4 are implemented by specifically-configured hardware (e.g., by one or more application-specific integrated circuits (ASICs) which are included) separate from or in lieu of the processor 510. Some embodiments incorporate more than one of the described operations or functionality in a single ASIC. In some embodiments, the operations and functionality are realized as functions of a program stored in a non-transitory computer-readable recording medium. Examples of a non-transitory computer-readable recording medium include, but are not limited to, external/removable or internal/built-in storage or memory unit, e.g., one or more of an optical disk, such as a DVD, a magnetic disk, such as a hard disk, a semiconductor memory, such as a ROM, a RAM, a memory card, and the like.

In some embodiments, the neural network model described herein is based on Deep Learning architecture. For the example, the model may be a convolutional neural network (CNN) model that can take advantage of Deep Learning concepts to solve the intractable representation problems. The model may have any CNN configuration known in the art. For the example, the model may be a super resolution CNN (SRCNN) that can take advantage of Deep Learning concepts to convert a low resolution image into a high resolution image. The model may have any SRCNN configuration known in the art. The neural network model of the neural network subsystem 160 is trained using classified test images. The CNN model is trained by the classified test images provided to the neural processor 161 before the probe mark inspection. The classified tested images may be stored in storage unit 162 in advance. In some embodiments, The classified tested images are provided from the data server 152. The neural processor 161 may implement convolutional neural network for identification of image specification in the test images 200.

Through the operations of the various embodiments above, the test system and the test method provided by the present disclosure provide an automatic process to increase the productivity in testing a wafer by integrating optic image investigation tool to neural network system to classify wafers according to probe marks inspection. it significantly reduces manual effort, errors made thereby, and further to enhance overall productivity.

While the disclosure has been described by way of example(s) and in terms of the preferred embodiment(s), it is to be understood that the disclosure is not limited thereto. Those skilled in the art may make various changes, substitutions, and alterations herein without departing from the spirit and scope of the present disclosure. In view of the foregoing, it is intended that the present invention cover modifications and variations of this invention provided they fall within the scope of the following claims.

What is claimed is:

1. A test system, comprising:
an assessment subsystem configured to receive a test image of a tested wafer from a probe apparatus;
a neural network subsystem; and
a process control processor configured to control, in response to the probe apparatus obtaining the test image, the assessment subsystem to perform an assessment operation to transmit the test image to the neural network subsystem in an automation mode,
wherein the neural network subsystem is configured to identify an image specification of probe marks in the test image and to generate an analyzed data of the test image to the assessment subsystem,
wherein the assessment subsystem is further configured to generate a first probe mark inspection result based on the analyzed data to the process control processor for generating a test result.

2. The test system of claim 1, wherein the assessment subsystem is further configured to generate, by comparing the test image and an analyzed image in the analyzed data, a training data to the neural network subsystem,
wherein the training data includes the test image and a corresponding identification data.

3. The test system of claim 2, wherein the neural network subsystem is further configured to be trained by the training data to update weight values in a neural network model operating in a neural network processor in the neural network subsystem.

4. The test system of claim 1, wherein the image specification includes coordination of the probe marks, an amount of the probe marks, inspection of a substrate of at least one pad in the tested wafer, or the combinations thereof.

5. The test system of claim 1, wherein the assessment subsystem is configured to compare the analyzed data with a plurality of quality thresholds, and to generate the first probe mark inspection result indicating a first failure result when at least one value in the analyzed data fails to meet a corresponding threshold in the plurality of quality thresholds.

6. The test system of claim 5, wherein the process control processor is further configured to generate the test result indicating a second failure result in response to the first probe mark inspection result indicating the first failure result.

7. The test system of claim 5, wherein the analyzed data includes distances between the probe marks and edges of pads in the tested wafer.

8. The test system of claim 1, further comprising:
a database subsystem comprising a data server configured to store the test image, the analyzed data and the first probe mark inspection result in a list data,
wherein the assessment subsystem is further configured to access the list data and to generate a second probe mark inspection result based on the list data and a second quality threshold.

9. The test system of claim 8, wherein the neural network subsystem is further configured to access the list data and to be trained by a training data to update a neural network model operating in the neural network subsystem.

10. The test system of claim 1, wherein the assessment subsystem is further configured to perform the assessment operation for a plurality of images of a plurality of lots according to a work queue provided by the process control processor.

11. A test method, comprising:
obtaining, by a probe apparatus, a plurality of test images of a lot of wafers;
marking, by a neural network subsystem, the plurality of test images based on a corresponding image specification of probe marks in each the plurality of test images to generate a plurality of marked images in a plurality of analyzed data;
comparing, by an assessment subsystem, the plurality of test images and the plurality of marked images to generate a comparison result for each of the wafers in the lot;
in response to the comparison, generating a first probe mark inspection result; and
updating a record, corresponding to the lot of wafers, in a process control processor according to the first probe mark inspection result.

12. The test method of claim 11, wherein the corresponding image specification of the probe marks includes coordination of the probe marks, an amount of the probe marks, inspection of a substrate of pads in the lot of the wafers, distances between the probe marks and edges of the pads in the lot of the wafers, or the combinations thereof.

13. The test method of claim 12, further comprising:
determining whether the plurality of analyzed data meet a plurality of quality thresholds to generate a second mark inspection result.

14. The test method of claim 11, wherein when the comparison result indicates an accurate result, the generating the first probe mark inspection result comprises:
in response to the comparison result, generating the first probe mark inspection result indicating a pass result.

15. The test method of claim 14, wherein when at least one mark on the plurality of marked images mismatches a correcting mark, the corresponding comparison result indicates an inaccurate result.

16. The test method of claim 15, further comprising:
generating a plurality of training data according to the correcting mark and the plurality of test images; and
training a neural network model in the neural network subsystem according to the plurality of training data.

17. The test method of claim 11, wherein the corresponding image specification of the probe marks includes an amount of the probe marks on a pad in one, corresponding to a wafer in the lot of wafers, of the plurality of test images,
wherein the test method further comprises:
when the amount of the probe marks on the pad in one of the plurality of analyzed data is greater than a threshold, generating a second probe mark inspection result indicating a failure result; and
updating the record according to the second probe mark inspection result.

18. The test method of claim 11, wherein the corresponding image specification of the probe marks includes inspection of a substrate of pads in the lot of the wafers and an amount of the probe marks on a first pad of the pads in one, corresponding to a wafer in the lot of wafers, of the plurality of test images,
wherein the test method further comprises:
when the inspection of the substrate indicates that no material of the substrate appears on at least one pad of the pads, determining whether the amount of the probe marks on the first pad is greater than a first threshold; and
when the amount of the probe marks on the first pad is greater than the first threshold, generating a second probe mark inspection result indicating a failure result.

19. The test method of claim 18, further comprising:
when the amount of the probe marks on the first pad is less than the first threshold, generating the second probe mark inspection result indicating a pass result; and
dispatching the lot of the wafer from the probe apparatus to a process stage.

20. The test method of claim 18, further comprising:
when the amount of the probe marks on the first pad is less than the first threshold, determining whether distances between the probe marks on the first pad and edges of the first pad is within a second threshold; and
when the distance is out of a range of the second threshold, generating the second probe mark inspection result indicating the failure result.
